(19) United States
(12) Patent Application Publication
(10) Pub. No.: US 2008/0203897 A1
(43) Pub. Date: Aug. 28, 2008

(54) Light Source Comprising Led Arranged in Recess

(75) Inventors: Marc Andre De Samber, Eindhoven (NL); Koen Van Os, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/912,346

(22) PCT Filed: Apr. 21, 2006
(86) PCT No.: PCT/IB2006/051244

§ 371 Date: Oct. 23, 2007

(30) Foreign Application Priority Data
Apr. 28, 2005 (EP) 05103483.3

(51) Int. Cl. H01J 1/62; H01L 33/00

(52) U.S. Cl. 313/498

(57) ABSTRACT

A light source comprising a substrate (1) having a first side and an opposing second side, at least one recess (2) being arranged in said first side of said substrate, a circuitry (4) at least partly arranged on said substrate (1), and at least one LED (3) being arranged in said at least one recess (2) and connected to said circuitry (4) is provided. The surface of said at least one recess (2) is continuous and is physically separated from said second side by substrate material. By arranging the LED in such a recess in the substrate, cross talk between adjacent LEDs is reduced, a good mechanical stability of the light source is maintained, and the thermal path through the substrate is reduced.

### TECHNICAL FIELD

The present invention relates to a light source comprising a substrate having a first side and an opposing second side, at least one recess being arranged in said first side of said substrate, a circuitry at least partly arranged on said substrate, and at least one LED being arranged in said at least one recess and connected to said circuitry.

### TECHNICAL BACKGROUND

Arrays of high-efficiency and high-brightness LEDs are presently considered for use as light sources. To make this feasible, a plurality of individual LEDs have to be assembled at a fine pitch on a substrate.

In multi-LED applications, with several LEDs located at a fine pitch on the substrate, it is further desired to avoid cross-talk between LEDs, that is that light, which is emitted from the sidewalls of the LEDs, couples into a neighboring LED (optionally of a different color) and is absorbed there.

One way of preventing cross talk between LEDs is to locate the LEDs in recesses, so that the walls of the recesses prevent the cross talk between LEDs.

For instance, it has been suggested to lithographically build walls around the individual LEDs to prevent cross talk.

Another problem in multi-LED applications is that LEDs, and especially high power LEDs, dissipate a lot of heat energy when emitting light.

This heat dissipation presents limits on how long or with which power the LEDs can operate. Thus, it is much desired to obtain a good heat transport away from the LED.

One approach to solve the problem with heat dissipation and cross talk between adjacent LEDs is described in EP 1 253 650 A, referring to a light source comprising a substrate defining an aperture extending between a first and a second opposing side and a platform covering an opening of the aperture adjacent to the first surface. By placing the LED in an aperture in the substrate, cross talk between adjacent LEDs in separate apertures is solved. By arranging the LED on a platform arranged on one side of the substrate, the platform may form an efficient heat dissipating thermal path and the substrate may suitably be made of a thermally insulating material without affecting the thermal path.

However, in this approach there is a need to arrange this platform on the backside of the substrate and see to that the LED is electrically isolated from the platform, which suitably is made of a metallic compound. This necessitates additional manufacturing steps, which may be unwanted.

Thus, there still remains a need for a LED-based lighting device that is easily produced and provides improved heat transport away from the LEDs. Especially there is a need for such devices with a reduced cross talk between neighboring LEDs.

### SUMMARY OF THE INVENTION

It is an object of the present invention to overcome at least part of the problems of the prior art, and to provide a multi-LED light source with reduced cross talk between individual LEDs and an improved heat sinking.

Thus, in one aspect the present invention provides a light source comprising a substrate having a first side and an opposing second side. At least one recess is arranged in the first side of the substrate, a circuitry is arranged on the substrate and at least one LED is arranged in the at least one recess and connected to the circuitry. The LED and the circuitry are electrically isolated from the substrate.

In a light source of the present invention, the surface of the at least one recess is continuous and is physically separated from the second side of the substrate-by-substrate material.

An advantage of the present invention is that arrangement of LEDs in recesses in the substrate reduces cross talk between adjacent LEDs in separate recesses.

Another advantage is that the thermal path between the LED and the second side is reduced, and thereby, the thermal resistance is reduced, allowing for better heat sinking.

A further advantage is that the substrate material, being either a dielectric substrate material or a conducting or semi-conducting material having an electrically isolating surface layer, electrically isolates the LED, arranged in the recess, from the second side of the substrate.

In embodiments of the present invention, a heat sink is arranged on the second side of said substrate, and the LED is in thermal contact with said heat sink, at least partially, via the substrate material, which separates the surface of the recess and the second side of the substrate.

An advantage with a light source according to this embodiment is that the heat sink will be electric isolated from LED, due to the dielectric substrate material between the LED and the heat sink, and this obviates the need for additional isolating layers between the LED and the heat sink.

Another advantage with this embodiment is that the heat sink is in thermal contact with the LED through the thin wall of substrate material forming the bottom of the recess.

In embodiments of the present invention, the sidewall of the recess or at least part of the sidewall of the recess is tapered, such that the opening towards the first side of the substrate is larger than the bottom area of the recess. Preferably, this sidewall thus being tapered outwards towards the first side of the substrate is a reflecting surface.

An advantage with this embodiment is that light emitted by the LED in the recess is transported out of the recess through the opening towards the first side of the substrate, even if the light is emitted in a direction parallel to the surface of the substrate or downwards into the recess. This increases the efficiency of the light source.

In embodiments of the present invention, an optical element, such as for example a lens, a collimator and/or a color converter is arranged on the first side of the substrate covering a recess, and thus any LED arranged in that recess, to receive at least a portion of light emitted by that LED.

In embodiments of the present invention, the above-mentioned optical element comprises a recess, in which the substrate of the light source is arranged.

An advantage with this embodiment is that this recess allows for easy arrangement of the optical element on the substrate with a predetermined position and/or orientation. Another advantage is that the portions of the optical element that extends down the sides of the periphery of the substrate may collect light emitted by the LED at oblique angles or parallel to the surface of the substrate. This increases the efficiency of the light source as even more of the emitted light is utilized.

In embodiments of the present invention, the LED is connected or connectable to a LED-driver via the second side of the substrate, i.e. the circuitry, to which the LED is connected, has a portion, which is located on the second side of the substrate. The connection between the LED, on the first side of the substrate, and the second side of the substrate could for example be done via a hole from the first to the second side, or via an edge side of the substrate.

An advantage with this embodiment is that elements that optionally may be arranged on top of the substrate, such as optical lenses, color filters and collimators, etc may be designed to have portions extending down the edge sides of the substrate, without obstructing the connection of the light source to a LED-driver. One example of this is the above-mentioned optical element having a recess in which the substrate is arranged.

In embodiments of the present invention, the connection between a LED and a circuitry is located in the recess.

An advantage with this embodiment is that if the upper surface of the LED is located beneath the plane of the first side of the substrate, optical elements, such as described above may be arranged directly on the surface of the substrate.

In embodiments of the present invention, a luminescent compound is arranged in said recess, at least partly covering a LED arranged in the recess, to receive light emitted by that LED.

Such luminescent compounds may be used to convert the color of the light emitted by the LED into a different color.

An advantage with this embodiment is that the luminescent compound may be arranged covering both the top and the sides of the LED. This allows for a good efficiency as essentially all light emitted by the LED will pass through the luminescent compound before exiting the light-source.

Another advantage with this embodiment is that the arrangement of the luminescent compound in the recess does not hinder the possibilities to arrange an optical element on top of the substrate, as described above.

In embodiments of the present invention, a first LED is arranged in a first recess and a second LED is arranged in a second recess.

An advantage with this embodiment is that the cross talk between LEDs arranged in separate recesses is reduced, allowing a better control of the total light emitted by the light source.

Another advantage with this embodiment is that each recess provides a well-defined area of deposition for a luminescent compound, and adjacent recesses may be filled with different luminescent compounds with a low risk of cross-contamination. Thus, a multicolor light source may conveniently be manufactured using this approach and a plurality LEDs of only one color, however using different luminescent compounds in different recesses.

In embodiments of the present invention, the substrate comprises a conducting or semi-conducting material having an electrically isolating surface layer isolating at least the LED and the circuitry from the substrate. In the case of a heat sink of a electrically conducting material, it may be advantageous that also the heat sink is isolated from the substrate by such an electrically isolating surface layer.

Examples of such a semi-conducting materials include silicon, which has a relatively high thermal conductivity. Silicon allows for good thermal contact between the LED and the heat sink, is relatively cheap, and can easily be electrically isolated with a thin electrically isolating layer, such as for example with a thermally grown SiO₂ layer, giving the desired isolation between the surface of the recess and the second side of the substrate. Further, if silicon is used, active circuitry, such as transistors, diodes (for example photo diodes) and thermal sensors etc, may be integrated into the substrate.

In embodiments of the present invention, surface of the recess and the second side of the substrate is separated by at least 10-100 μm, preferably 25-75 μm, of substrate material.

A thickness in this range allows for good thermal transport through the substrate and at the same time, good mechanical stability of the whole construction.

This and other aspects of the present invention will now be described in more detail, with reference to the appended drawings showing exemplary embodiments of the invention, in which common features in the different drawings have the same reference numbers, and which drawings are not drawn to scale.

### BRIEF DESCRIPTION OF THE DRAWINGS

FIG. 1 illustrates in cross section a part of a light source according to the present invention.

FIG. 2 illustrates in perspective a light source according to the present invention.

FIG. 2a illustrates the substrate before the LEDs are arranged.

FIG. 2b illustrates the substrate in FIG. 2a provided with LEDs in the recesses.

### DETAILED DESCRIPTION OF PREFERRED EMBODIMENTS

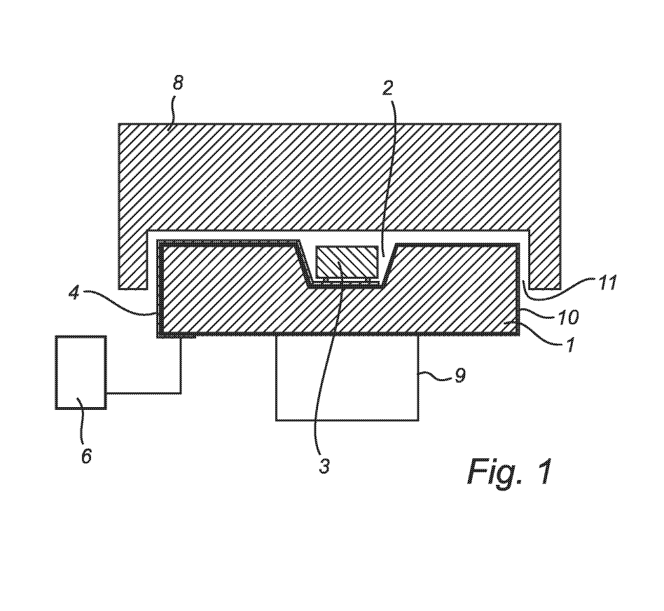

An exemplary embodiment of a light source according to the present invention is shown in FIG. 1.

A silicon substrate 1 is provided, having an electrically isolating surface layer 10 of SiO₂, and a recess 2 is provided in the front side of the substrate. In the recess 2, a light-emitting diode (LED) 3 is arranged. The recess 2 is tapered, having a larger opening area than bottom area.

The LED 3 is connected to a circuitry 4, which is arranged on the substrate 1 and in the recess 2. The connection between the LED 3 and the circuitry 4 is provided by solder bumps on the bottom side of the LED.

The circuitry 4 is connected to a LED-driving unit 6 via a contact on the backside of the substrate 1, via one edge side of the substrate.

A light collimator 8 is arranged to collimate light emitted by the LED 3, and comprises a recess in which the substrate 1 is arranged, such that the collimator 8 extends partly down the edge sides of the substrate 1.

A heat sink 9 is also arranged on the backside of the substrate, at a location corresponding to the position of the LED 3, to transport heat dissipated by the LED away from heat sensitive components of the light source, such as the LED 3 itself.

In the embodiment shown in FIG. 1, the substrate 1 is a silicon substrate. As silicon is a semi-conducting material, the surface of the substrate is provided with an isolating layer 10 of SiO₂ to isolate the circuitry, the LED and other components of the light source in order to avoid short-circuiting. SiO₂ is an attractive candidate for the isolating layer on a silicon substrate, as it provides an effective isolation while it does not hamper the relatively high thermal conductivity of the silicon material to any appreciable extent. As will be apparent to those skilled in the art, other substrate materials may be used. For example, dielectric substrate material known to those skilled in the art, such as for example ceramic substrates like Al₂O₃ or AlN, may be used, and in such cases, the electrically isolating layer 10 may be obviated. In addition, other conducting or semi-conducting materials that can be provided with an electrically isolating surface layer may be used as substrate materials in a light source of the present invention.

Methods to provide a semi-conducting or conducting substrate material with an isolating surface layer are known to those skilled in the art. In the case of a silicon substrate, such methods include different methods to grow (for example thermally) an oxide layer on the surface of the silicon substrate, i.e. providing a surface modification and methods to deposit an oxide layer, i.e. providing a coating. Thus, an isolating surface layer includes both surface modifications and coating.

In the case of a semi-conducting or conducting substrate material, at least the circuitry and the LED is isolated from the substrate, but typically, essentially the entire substrate is provided with an isolating surface.

Typically, the substrate is approximately 200 μm thick, but the thickness may vary widely with for example the type and thickness of the LED and the area of use.

The recess 2 in the substrate 1 is typically formed by removing material from the substrate, such as by etching or drilling. The recess is open to the front side of the substrate, and the surface of the recess is continuous, in the sense that it is free from openings towards the backside of the substrate.

The depth of the recess is typically such that there is in the range of 10-100 μm, for example 25-75 μm, of substrate material separating the deepest point of the recess from the backside of the substrate. Substrate material of such a thickness provides a low thermal resistance in the thermal path between the LED and the heat sink. Substrate material of such a thickness also provides a good mechanical stability at the location of the mounted LED.

The recess typically has a tapered shape, having a larger opening area than bottom area. This yields that the sidewalls of the recess is sloping outwards towards the front side. The sidewalls may further be reflective, either by processing the substrate material in the recess into a reflective surface or by coating the sidewalls with a reflective coating. Reflective sidewalls increase the efficiency of the light source as light emitted by a LED in the recess is reflected out of the recess even if it is originally emitted towards the sidewall.

Typically, the depth of the recess is such that the upper side of a LED arranged in the recess is below the plane of the front side of the substrate. Thus, the recess functions as a collimator, and light emitted in the direction parallel to the plane of the substrate is either reflected out of the recess or absorbed by the substrate material.

The LED 3 arranged in the recess 2 may be any type of LED known to those skilled in the art.

As used herein, the term “light emitting diode”, or “LED”, includes all types of light emitting diodes, including laser diodes, both inorganic based LEDs and organic LEDs, such as polyLEDs and OLEDs, capable of emitting light in a wavelength or wavelength interval from infrared to ultraviolet.

In the context of this application, there is distinguished between two types of LEDs: (i) LEDs with both the connectors to the anode and the cathode located on one side of the LED (commonly known as “flip-chip”-LEDs) and (ii) LEDs having the connectors to the anode and the cathode on separate sides of the LED (here denoted “wire-bond” LEDs).

Both these types of LEDs are suitable for use in the present invention. However, in certain applications of the present invention, the “flip-chip” type is preferred, as this type presents an essentially flat front surface and has a low profile. Presently, blue and green LEDs are available in “flip-chip” design whereas red LEDs are only available in “wire-bond” design.

The circuitry 4 is arranged on the substrate 1 to provide contact areas for LEDs and to provide contact areas for connection to a LED-driver. Typically, the circuitry 4 is constituted by an electrically conducting pattern applied on the substrate by methods known to those skilled in the art. Commonly used materials for the circuitry includes conducting metals, such as Al, Cu, Au, Ag, etc. and conducting alloys and compounds comprising such metals, but also conducting non-metallic compounds.

The design of the circuitry in, and in the surroundings of, the recess depends on the type of LED to be connected to the circuitry. Typically, for a “flip-chip” LED, connections for both the anode and the cathode of the LED are arranged in the bottom of the recess, forming a “foot print” on which the LED fits and is connected to. For a “wire-bond” LED, connections for the anode may be provided in the bottom of the recess, whereas connections for the cathode (the wire) are provided on the rim to the recess. However, if the recess is big enough, also the connections for the cathode may be provided on the bottom or sidewall of the recess.

In some embodiments of the present invention, the circuitry is connected or connectable to the LED-driving unit via the backside of the substrate. As shown in FIG. 1, the circuitry is arranged on the front side, down an edge side of the substrate, to the backside. An alternative way to solve this is to arrange the circuitry in a hole from the front side to the backside of the substrate.

Arranging a portion of the circuitry on the backside provides for easy connection of the light source to a sub-mount. Further, it also allows for an optical element, as the collimator shown in FIG. 1, to extend down the edge sides of the substrate.

In case of a plurality of LEDs arranged on the substrate, either in the same recess or in separate recesses, the circuitry may provide for independent addressing of each LED.

In the case of for example a silicon substrate, it is possible to integrate active components of the circuitry, such as for example transistors, diodes and sensors, in the silicon substrate material by method well known in the field of manufacture of integrated circuits.

The LEDs are typically connected to the circuitry by soldering, using commonly known electrically conducting soldering materials.

The LED-driving unit 6 provides the driving voltage for the LED it is connected to, and is of any type known to those skilled in the art. If desired, the LED-driving unit may allow for independent addressing of separate LEDs.

As shown in FIG. 1, a collimator 8 is arranged on the substrate 1 in order to collimate the light emitted by the LED 3. However, other optical elements may also be arranged on the substrate, alone or in combination with other optical elements. Such optical elements include, but are not limited to, lenses, color filters, color converters, diffusers, etc. For example, a lens for focusing the light may be arranged on top of a collimator, first collecting the light emitted by the device and then directing it in a certain direction, or focusing it on a certain point.

A color filter may be provided to select a certain wavelength or wavelength interval to be emitted by the light source.

A color converter may be used to convert the light emitted by the LEDs into a desired wavelength. Such a color converter may for example be a transparent or translucent element comprising a luminescent material.

As shown in FIG. 1, portions of the collimator partially extend down the peripheral side of the substrate. This is optional, but may in some cases increase the total efficiency of the light source, as light emitted in even very oblique angles are received by the collimator.

The heat sink 9 is arranged on the backside of the substrate 1 to transport heat dissipated by the LED in operation away from heat sensitive components of the device, such as the LED it self. Typically, the heat sink is of a material with a high thermal conductivity, such as a metal. Examples include metals in general, such as, but not limited to, Cu, W, Al, and alloys of such metals with high conductivity, as well as materials, such as AlSiC.

The heat sink is suitably arranged on the backside of the substrate at a location corresponding to the location of the LED in the recess, thus minimizing the thermal path from the LED to the heat sink. However, it may be suitable to arrange a contact layer between the substrate and the heat sink to properly bond them together, physically and/or thermally. Furthermore, as the circuitry is mainly arranged on the front side of the substrate, essentially the whole backside may be used as contact area to the heat sink, giving good heat sinking properties.

A luminescent material may be arranged in a recess 2, at least partly covering the LED(s) being arranged in that recess. The luminescent material may be used to convert the light emitted by the LED into a converted color, and luminescent materials for converting a first color into a second color is known to those skilled in the art for a great number of combinations of first and second colors. The efficiency of the color conversion is highest when light of a shorter wavelength, such as UV or blue, is converted into light of a higher wavelength, such as green or red.

One example of an application of such a luminescent material is converting blue or green light into red light. As mentioned above, presently, red LEDs are not available in “flip-chip” design, but in order to obviate the need for “wire-bond” LEDs to provide red light, a blue flip-chip LED may be covered by a blue-to-red converting material.

When a luminescent material is arranged in a recess, the walls of the recess form a natural barrier towards any adjacent recess. This allows separate luminescent materials to be deposited in adjacent recesses with a low risk of cross contamination.

Luminescent materials may be deposited in a recess to cover the LED(s) in that recess and to fill the recess. The luminescent material may form a surface below or in the plane of the front side of the substrate. In such cases, the luminescent material does not form any obstruction for arranging an optical element, such as a lens, a collimator, etc, on top of the substrate. However, the luminescent material may also form a surface above the plane of the front side of the substrate, for example a convex surface. In such a case, the luminescent material acts as a focusing lens it self, in addition to its color converting properties.

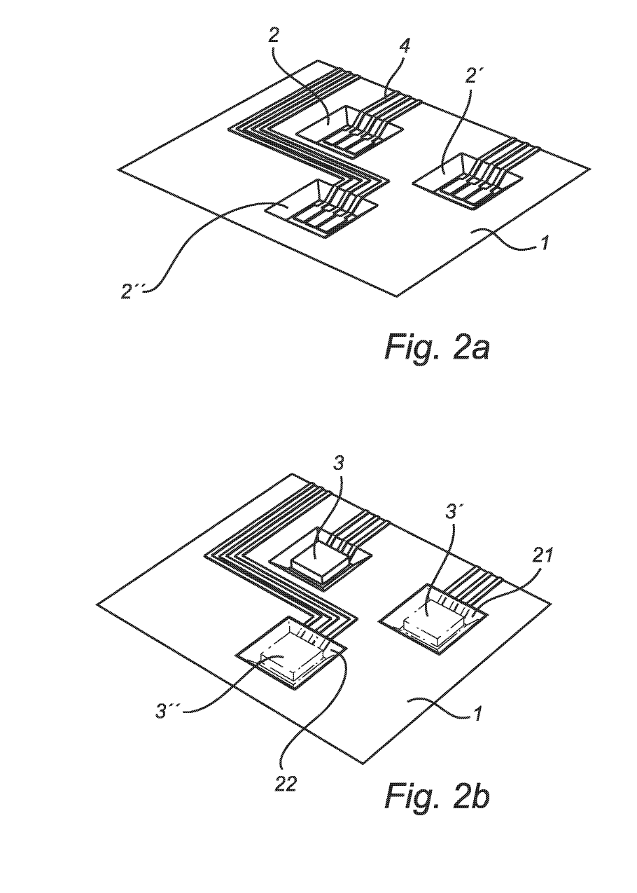

A second exemplary embodiment of the present invention is shown in FIGS. 2a and 2b, and comprises a substrate 1 with a plurality of recesses, 2, 2′, 2″ and one LED 3, 3′, 3″ arranged in each recess. Each LED is connected to the circuitry 4, but is independently addressable in order to tailor the total light produced by the light source.

The three LEDs 3, 3′, 3″, all produce a separate color, here exemplified by blue, green and red light, respectively.

In the embodiment shown in FIG. 2b, all three LEDs are blue LEDs. However, the LED that produces green light is a blue LED covered by a blue-to-green converting luminescent material 21, and the LED producing red light is a blue LED covered by a blue-to-red converting luminescent material 22. As each LED is driven independently, the light source of this embodiment represents a color variable RGB-pixel.

On the backside of the substrate (not shown in FIG. 2), a heat sink may be arranged, which could comprise one common heat sink for all the LEDs or one separate heat sink per LED.

In other embodiments of the present invention, no luminescent material is used, and each color in the pixel is produced by a LED inherently emitting this color.

Thus, the recess in the substrate may have one or more of the following effects: (i) to reduce the thermal resistance between the LED and the heat sink without the need for direct connection through holes through the substrate, (ii) to reduce optical cross-talk between adjacent LEDs located in adjacent recesses, (iii) at least in the case of flip-chip LEDs, to provide a flat surface on the front side of the substrate, (iv) to provide a well defined area for deposition of luminescent materials and (v) to facilitate for the arrangement of an optical element on top of the light-source.

Light sources according to the present invention may be produced by a method comprising procedures well known to those skilled in the art.

Typically, a plurality of light sources are produced or at least partly produced parallel on a large wafer of substrate material, such as a conventional silicon wafer, and afterwards, the wafer is suitably diced into smaller units.

First, the recess locations are defined on one side of the silicon wafer by patterning a hard etch mask (SiO₂/Si₃N₄). The same mask material is deposited on the backside of the wafer, to fully protect this side from the following etching.

The recesses are etched out of the substrate by KOH etching to a depth of 10-100 μm less than the thickness of the wafer, i.e. not all the way through the wafer, where after the etch mask is removed. The residual wafer material in the bottom of the recess will serve as thermal path and electrical isolation in the finalized product.

To prepare for electrical connections between the front and the backside of the substrate, holes are made through the substrate at the location for these connections, for example by laser ablation. These holes may for example be in the form of slits.

To prepare for deposition of the circuitry, the surfaces of the silicon wafer are oxidized (the front side, backside, in the recesses and in the through-holes) to provide an electrically isolating surface layer.

The circuitry is arranged as a metallization of a desired pattern in the recesses, on the front side, in the through-substrate holes and on the backside of the wafer. The patterned deposition of the circuitry may for example be obtained by patterning a resist layer on the isolated parts of the wafer by conventional lithographic techniques, followed by deposition of a metal and subsequent removal of the resists.

Optionally, the sidewalls of the recesses are then processed into reflective surfaces.

LEDs are arranged in the recesses and connected to the circuitry by soldering, and the wafer is diced into separate light sources. By cutting the wafer through the through-wafer slits, side contacts are exposed as going from the front side to the backside at a peripheral edge of the substrate.

Filling the recesses with luminescent materials, as described above, may be performed before or after the dicing of the wafer.

Optical elements are preferably arranged on the diced substrates, in order to utilize the above-mentioned advantages with the front-to-back contacts.

The heat sink may be arranged on the backside of the diced substrate by means of a bonding layer with high thermal conductivity.

The person skilled in the art realizes that the present invention by no means is limited to the preferred embodiments described above. On the contrary, many modifications and variations are possible within the scope of the appended claims. For example, a light source for white light may be produced by using blue LEDs and using a blue-to-yellow converting luminescent material, either as a luminescent compound deposited in the recesses or as a luminescent material in an optical element arranged on the substrate, where the white light is obtained by the yellow converted light and residual non-converted blue light.

Furthermore, the method described above is for a silicon substrate. Other substrate materials may require different processing conditions for the production of a light source of the present invention. For example, conducting or semi-conducting substrate material materials other than silicon may require other methods to obtain an electrically isolating surface layer, and intrinsic dielectric substrate materials may not require any electrically isolating layer at all.

1-11. (canceled)

12. A light source comprising a substrate (1) having a first side and an opposing second side, at least one recess (2) being arranged in said first side of said substrate, a circuitry (4) being arranged on said substrate (1), and at least one LED (3) being arranged in said at least one recess (2) and connected to said circuitry (4), said LED (3) and said circuitry (4) being electrically isolated from said substrate, wherein
the surface of said at least one recess is continuous and is physically separated from said second side by substrate material; and
said at least one recess is at least partly filled with a luminescent compound (21) deposited in said recess (2′) to cover the at least one LED (3′).

13. A light source according to claim 12, wherein said at least one recess is filled with said luminescent compound in such a way as to form a surface below or in a plane of said first side of the substrate.

14. A light source according to claim 12, wherein said at least one recess is filled with said luminescent compound in such a way as to form a surface above a plane of said first side of the substrate.

15. A light source according to claim 12, wherein a heat sink (9) is arranged on said second side of said substrate (1), and said LED (3) is in thermal contact with said heat sink (9), at least partially via said substrate material separating said surface of said recess (2) and said second side of said substrate (1).

16. A light source according to claim 12, wherein said recess (2) comprises a reflective sidewall being tapered outwards towards said first side of said substrate.

17. A light source according to claim 12, wherein an optical element (8) is arranged on said first side of said substrate (1) to receive at least a portion of light emitted by said at least one LED (3).

18. A light source according to claim 17, wherein said optical element (8) comprises a recess (11), said substrate (1) being arranged in said recess (11) of said optical element (8).

19. A light source according to claim 12, wherein said circuitry (4) is connectable to a LED-driver (6) via said second side of said substrate.

20. A light source according to claim 12, wherein the connection between at least one LED (3) and said circuitry (4) is located in said recess (2).

21. A light source according to claim 12, comprising a first LED (3) arranged in a first recess (2) and a second LED (3′) arranged in a second recess (2′).

22. A light source according to claim 12, wherein said substrate (1) comprises a conducting or semi-conducting material having an electrically isolating surface layer (10) which isolates at least said LED (3) and said circuitry (4) from said substrate (1).

23. A light source according to claim 22, wherein said substrate (1) comprises silicon.

24. A light source according to claim 12, wherein the surface of said recess (2) and said second side of said substrate is separated by at least 10-100 μm, preferably 25-75 μm, of substrate material.
